(19) United States
(12) Patent Application Publication
(10) Pub. No.: US 2014/0167779 A1
(43) Pub. Date: Jun. 19, 2014

(54) Ground Fault Detection System for a Power Supply System

(71) Applicant: CATERPILLAR INC., Peoria, IL (US)

(72) Inventor: Baojun Si, Dunlap, IL (US)

(73) Assignee: Caterpillar Inc., Peoria, IL (US)

(21) Appl. No.: 13/718,184

(22) Filed: Dec. 18, 2012

(51) Int. Cl. G01R 31/02

(52) U.S. Cl. CPC G01R 31/025
USPC 324/509

(57) ABSTRACT

A ground fault detection system may include a direct current (DC) voltage source and an alternating current (AC) device. The ground fault detection system may also include an inverter, coupled to the DC voltage source, the AC device and an electrical ground, including: a positive rail, a negative rail and a plurality of switch elements, wherein each of the plurality of switch elements may be coupled to the positive rail, the negative rail and the AC device. The ground fault detection system may further include a voltage monitoring device coupled to the positive rail, the negative rail and the electrical ground and an electronic controller, coupled to the inverter and the voltage monitoring device configured to: control the plurality of switching elements, sample a voltage potential across the voltage monitoring device at predetermined time periods and determine a ground fault of the inverter based at least in part on the sampled voltage potential and the predetermined time periods.

### TECHNICAL FIELD

The disclosure relates generally to a ground fault detection system for a power supply system. More particularly, the disclosure relates to a ground fault detection system that determines a fault in a power supply system by monitoring a voltage potential across a ground resistor.

### BACKGROUND

Known power supply systems convert direct current (DC) power, supplied from a DC source (e.g., battery, generator set, etc.), to alternating current (AC) power using an inverter or other electric power conversion circuit. The AC power may be supplied to an AC motor or other loads. The DC source used in the power supply system provides a high voltage and has a large capacity. Thus, if an electric fault arises in any part of the electric circuit, there is a possibility of such trouble as an electric shock to an engineer who performs maintenance of system. For this reason, it is required for the power supply system to detect a fault as soon as possible.

One attempt to detect a leakage in a power supply system is described in U.S. Pat. No. 8,004,285 (the '285 patent) issued to Endou on Aug. 23, 2011. The '285 patent discloses a leakage device that can be correctly performed both in a DC high voltage circuit and in an AC high voltage circuit in a vehicle-mounted power supply system. Under a state where a contacter is turned off, all insulated-gate bipolar transistor (IGBT) elements (switching element) in an IGBT invert circuit are turned on, and an AC signal V is applied to an applying point P. Then a voltage measured at a voltage measurement point Q is compared with a threshold value to detect whether or not the leakage exits.

Although the system of the '285 patent may be helpful in detect leakage in a vehicle-mounted power supply system, the system is limited. That is, the system of the '285 patent may be inapplicable to identify an individual faulty wire of a plurality of wires of an inverter circuit. Moreover, the system of the '285 patent requires a sum of three phase (each 60 degree point of the fundamental output waveform) of the inverter circuit to detect a leakage of the power supply system. This increases cost, time, and/or power to detect a leakage of the vehicle-mounted power supply system.

Accordingly, there is a need to efficiently identify each individual faulty wire of a plurality of wires of an inverter circuit of a power supply system.

### SUMMARY

The foregoing needs are met, to a great extent, by the disclosure, wherein in one aspect a system and a method are provided for determining which phase of an inverter circuit caused a ground fault for a power supply system.

In accordance with one embodiment, a power system may include a direct current (DC) voltage source and an alternating current (AC) device. The power system may also include an inverter, coupled to the DC voltage source, the AC device and an electrical ground, including: a positive rail, a negative rail, and a plurality of switch elements, wherein each of the plurality of switch elements is coupled to the positive rail, the negative rail and the AC device. The power system may further include a voltage monitoring device coupled to the positive rail, the negative rail and the electrical ground; and an electronic controller, coupled to the inverter and the voltage monitoring device. The electronic controller is configured to: control the plurality of switching elements, sample a voltage potential across the voltage monitoring device at predetermined time periods, and determine a ground fault of the inverter based at least in part on the sampled voltage potential and the predetermined time periods.

In accordance with another embodiment, a method for detecting ground fault of a power system may include detecting outputs of a plurality of phases of an inverter circuit including a positive rail, a negative rail, and a plurality of switch elements and identifying one or more time periods when an output of one phase of the plurality of phases is different from the outputs of the remaining phases of the plurality of phases of the inverter circuit. The method may also include detecting a voltage potential across a voltage monitoring device that is coupled to the positive rail and the negative rail; and determining a ground fault of the power supply system based at least in part on the voltage potential across the voltage monitoring device during the one or more periods.

### BRIEF DESCRIPTION OF THE DRAWINGS

FIG. 1 shows a power supply system according to an embodiment of the present disclosure.

FIG. 2 shows an inverter circuit of the power supply system according to an embodiment of the present disclosure.

FIG. 3 shows an output voltage waveform of an inverter circuit during a first time period according to an embodiment the present disclosure.

FIG. 4 shows an output voltage waveform of an inverter circuit during a second time period according to an embodiment of the present disclosure.

FIG. 5 shows an output voltage waveform of an inverter circuit during a third time period according to an embodiment the present disclosure.

FIG. 6 shows a flowchart of a method of detecting ground fault of a power supply system according to an embodiment of the present disclosure.

### DETAILED DESCRIPTION

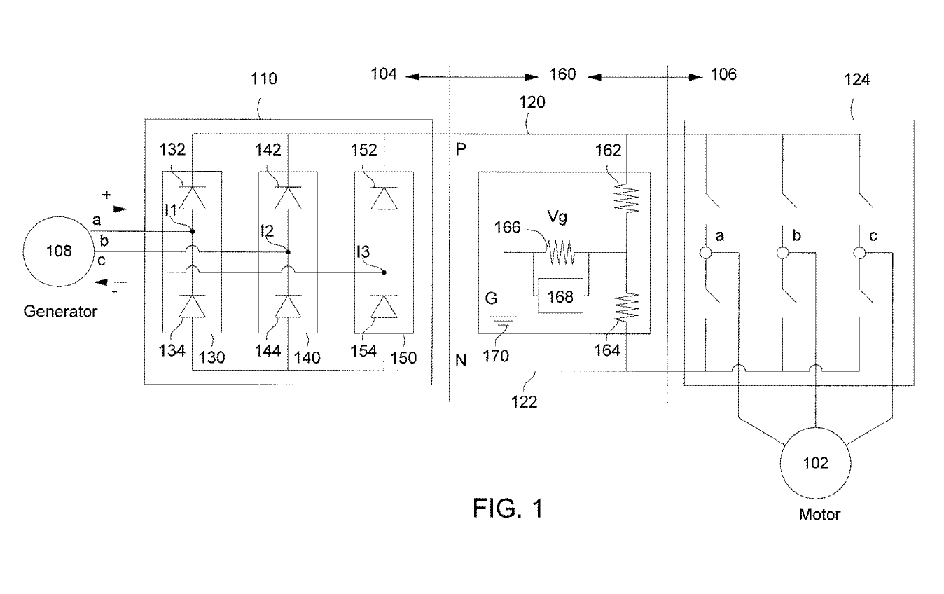

FIG. 1 shows a power supply system 100 according to an embodiment of the present disclosure. More specifically, FIG. 1 illustrates an exemplary power supply system 100 according to an embodiment of the present disclosure. The power supply system 100 may be configured to provide power to an external load 102. The power supply system 100 may comprise a direct current (DC) circuitry 104, an alternating current (AC) circuitry 106 and a ground fault detection circuitry 160. In one exemplary embodiment, the power supply system 100 may be configured as a primary source of power, if desired. It is contemplated, however, that in some embodiments, the power supply system 100 may provide an immediate supply of back power provided to the external load 102 when power supplied from an external power source is interrupted.

As shown in FIG. 1, the power supply system 100 may include a DC circuitry 104 and an AC circuitry 106. The DC circuitry 104 may include a power generator 108 and a rectifying element 110. The power generator 108 may be a three-phase alternating power source configured to generate an alternating current. The rectifying circuit 110 may convert the alternating power generated by the power generator 108 into DC power. The rectifying circuit 110 may be a three-phase full-wave bridge rectifier circuit. For example, the rectifying circuit 110 may include three-sets of full-wave rectifier circuits 130, 140 and 150. Each of the three-sets of full-wave rectifier circuits 130, 140 and 150 include a plurality of diodes. For example, the first set of full-wave rectifier circuit 130 may include a first diode 132 and a second diode 134. The second set of full-wave rectifier circuit 140 may include a third diode 142 and a fourth diode 144. The third set of full-wave rectifier circuit 150 may include a fifth diode 152 and a sixth diode 154. Each of the three-sets of full-wave rectifier circuits 130, 140 and 150 may include an intermediate point (I) coupled to different phases of the power generator 108. For example, the first set of full-wave rectifier circuit 130 may include a first intermediate point (I1) coupled to a first phase of the power generator 108. The second set of full-wave rectifier circuit 140 may include a second intermediate point (I2) coupled to a second phase of the power generator 108. The third set of full-wave rectifier circuit 150 ma include a third intermediate point (I3) coupled to a third phase of the power generator 108.

A positive line 120 and a negative line 122 may be coupled to a positive terminal and a negative terminal of the rectifying circuit 110. Also, the positive line 120 and the negative line 122 may be coupled to a positive terminal and a negative terminal of the AC circuitry 106. The AC circuitry 106 may include an inverter circuit 124 coupled to the positive line 120 and the negative line 122. The inverter circuit 124 may convert the DC power from the power generator 108 to an alternating current power and supply the alternating current power to power the external load 102. In an exemplary embodiment, the external load 102 may be a three-phase motor having three coils corresponding to each phase.

The ground fault detection circuitry 160 may be coupled to the positive line 120 and the negative line 122. The ground fault detection circuitry 160 may be arranged in parallel with the rectifying circuit 110 and the inverter circuit 124. The ground fault detection circuitry 160 may comprise a plurality of resistors. For example, the ground fault detection circuitry 160 may include three resistors. In an exemplary embodiment, the ground fault detection circuitry 160 may include a first resistor 162 coupled to the positive line 120 and a second resistor 164 coupled to the negative line 122. A voltage monitoring resistor 166 may be coupled to the first resistor 162, the second resistor 164 and an electrical ground 170. In an exemplary embodiment, the terminal of the voltage monitoring resistor 166 that is coupled to the first resistor 162 and the second resistor 164 may be biased as the positive terminal while the terminal of the voltage monitoring resistor 166 that is coupled to the electrical ground 170 may be biased as the negative terminal. In another exemplary embodiment, the terminal of the voltage monitoring resistor 166 that is coupled to the first resistor 162 and the second resistor 164 may be biased as the negative terminal while the terminal of the voltage monitoring resistor 166 that is coupled to the electrical ground 170 may be biased as the positive terminal.

The ground fault detection circuitry 160 may also comprise an electronic controller 168 that may monitor a voltage potential across the voltage monitoring resistor 166 during various time periods. For example, the electronic controller 168 may monitor a voltage potential across the voltage monitoring resistor 166 during different phases of the inverter circuit 124. The electronic controller 168 may also monitor the switching of a plurality of switching elements of the inverter circuit 124. For example, the electronic controller 168 may monitor an operation (e.g., switched on or off) of the plurality of switching elements of the inverter circuit 124 to identify a phase (e.g., a segment of an operation wave cycle) of the inverter circuit 124. The electronic controller 168 may determine a ground fault based at least in part on a voltage potential across the voltage monitoring resistor 166 and the switching of the plurality of switching elements of the inverter circuit 124. The electronic controller 168 may determine which phase of the inverter circuit 124 caused ground fault based at least in part on the voltage potential across the voltage monitoring resistor 166 during that phase of operation.

For example, the electronic controller 168 may correlate the voltage potential across the voltage monitoring resistor 166 with different phases of the inverter circuit 124 to determine which phase of the inverter circuit 124 caused ground fault. In an exemplary embodiment, the electronic controller 168 may monitor a voltage potential and/or current across the voltage monitoring resistor 166 when only one phase (e.g., phase A) of the inverter circuit 124 is coupled to the positive line 120 or the negative line 122 while the other phases (e.g., phases B and C) of the inverter circuit 124 are coupled to the opposite line. In the event that the voltage potential across the voltage monitoring resistor 166 is above or below a predetermine threshold, the electronic controller 168 may determine that phase A of the inverter circuit 124 caused the ground fault. In another exemplary embodiment, the electronic controller 168 may monitor a voltage potential across the voltage monitoring resistor 166 when only one phase (e.g., phase A) of the inverter circuit 124 is coupled to the positive line 120 while the other phases (e.g., phase B and C) of the inverter circuit 124 are coupled to the negative line 122. In the event that the voltage potential across the voltage monitoring resistor 166 is above or below a predetermine threshold, the electronic controller 168 may determine that phase A of the inverter circuit 124 caused the ground fault.

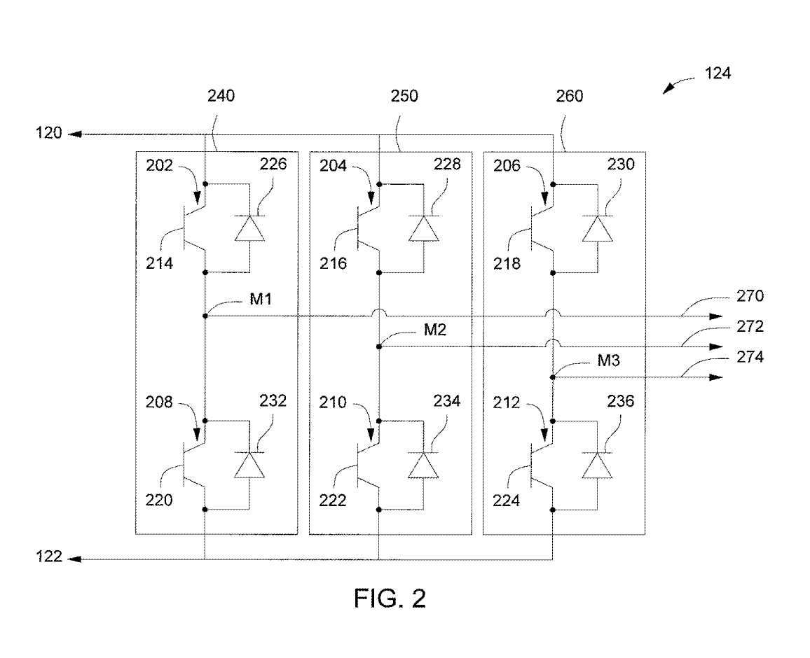

FIG. 2 shows an inverter circuit 124 of the power supply system 100 according to an embodiment of the present disclosure. As shown in FIG. 2, the inverter circuit 124 may be an insulated-gate bipolar transistor (IGBT) inverter circuit. For example, the inverter circuit 124 may comprise six IGBT switching elements 202-212 including six IGBT transistors 214-224 and six corresponding diodes 226-236. Each IGBT transistor and a corresponding diode forms a IGBT switching element in order to convert the DC power from power generator 108 to AC power to supply power to the external load 102. In an exemplary embodiment, the IGBT transistor 214 and a corresponding diode 226 may form a first IGBT switching element 202, the IGBT transistor 216 and a corresponding diode 228 may form a second IGBT switching element 204, the IGBT transistor 218 and a corresponding diode 230 may form a third IGBT switching element 206, the IGBT transistor 220 and a corresponding diode 232 may form a fourth IGBT switching element 208, the IGBT transistor 222 and a corresponding diode 234 may form a fifth IGBT switching element 210 and the IGBT transistor 224 and a corresponding diode 236 may form a sixth IGBT switching element 212.

The inverter circuit 124 may include three-sets of IGBT switching elements 240, 250 and 260 to provide three-phase power to the external load 102. Each of the three-sets of IGBT switching elements 240, 250 and 260 may include a plurality of IGBT switching elements. For example, a first-set of IGBT switching elements 240 may include a first IGBT switching element 202 and a fourth switching element 208, a second-set of IGBT switching elements 250 may include a second IGBT switching element 204 and a fifth switching element 210 and a third-set of IGBT switching elements 260 may include a third IGBT switching element 206 and a sixth switching element 212. Each set of the IGBT switching elements 240, 250 and 260 may include a middle point (M) between the plurality of IGBT switching elements. For example, the first-set of the IGBT switching elements 240 may include a first middle point (M1) located between the first IGBT switching element 202 and the fourth switching element 208. The second-set of IGBT switching elements 250 may include a second middle point (M2) located between the second IGBT switching element 204 and the fifth switching element 210. The third-set of IGBT switching elements 260 may include a third middle point (M3) located between the third IGBT switching element 206 and the sixth switching element 212.

The three middle points may be coupled to the external load 102 via a plurality of wires 270-274 to supply power to the external load 102. Each of the three middle points may supply a different phase of the power supply to the external load 102. In an exemplary embodiment, the external load 102 may be a three-phase motor having three coils. The first middle point (M1) may be coupled to a first coil of the external load 102 via the first wire 270 and supply a first phase of the power supply. The second middle point (M2) may be coupled to a second coil of the external load 102 via the second wire 272 and supply a second phase of the power supply. The third middle point (M2) may be coupled to a third coil of the external load 102 via the third wire 274 and supply a third phase of the power supply.

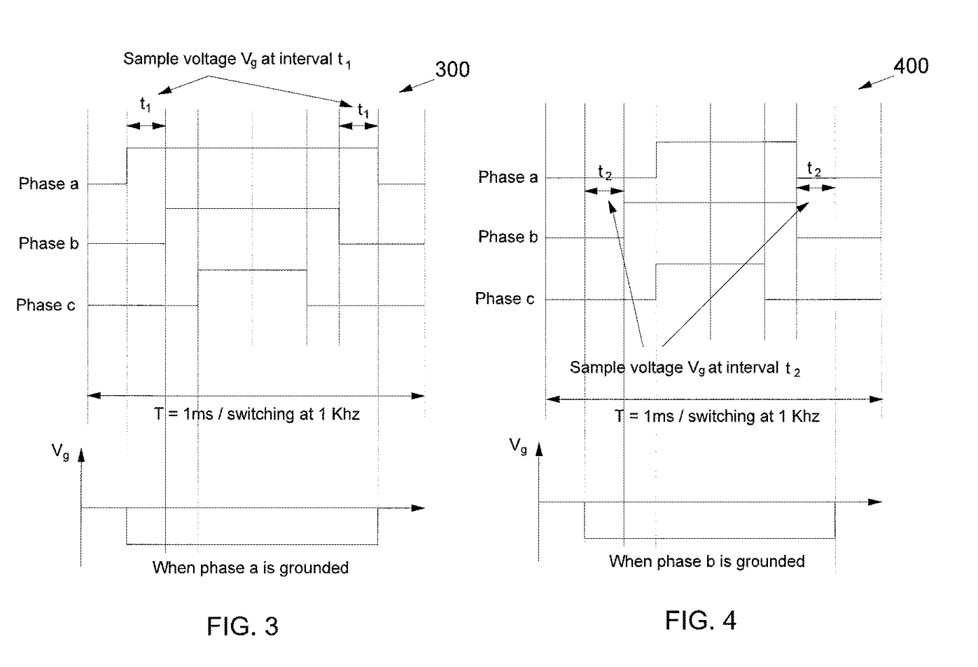

FIG. 3 shows a switching voltage waveform 300 of the inverter circuit 124 during a first time period according to an embodiment of the present disclosure. As shown in FIG. 3, the voltage waveform illustrates an operation of the inverter circuit 124 during a first time period (t₁). During the first time period (t₁), phase A of the inverter circuit 124 may be coupled to the positive line 120 (e.g., positive voltage potential) while phase B and phase C of the inverter circuit 124 may be coupled to the negative line 122 (e.g., negative voltage potential). In an exemplary embodiment, the first IGBT switching element 202 may be switched on and the fourth IGBT switching element 208 may be switched off to couple a positive voltage potential on the positive line 120 to the external load 102. As illustrated in the voltage waveform 300, phase A of the inverter circuit 124 may output a positive voltage potential (V_{dc}) during the first time period (t₁). In another exemplary embodiment, the second IGBT switching element 204 may be switched off and the fifth switching element 210 may be switched on to couple a negative voltage potential (−V_{dc}) on the negative line 122 to the external load 102. As illustrated in the voltage waveform 300, phase B of the inverter circuit 124 may output a reference voltage potential (e.g., 0V) during the first time period (t₁). In other exemplary embodiment, the third IGBT switching element 206 may be switched off and the sixth switching element 212 may be switched on to couple a negative voltage potential (−V_{dc}) on the negative line 122 to the external load 102. As illustrated in voltage waveform 300, phase C of the inverter circuit 124 may output a reference voltage potential (e.g., 0V) to the external load 102.

As illustrated in FIG. 3, only phase A of the inverter circuit 124 provides a positive output voltage potential to the external load 102 during the first time period (t₁). The electronic controller 168 may detect a voltage potential (V_{g}) across the voltage monitoring resistor 166 during the first time period (t₁) to determine whether phase A of the inverter circuit 124 is the cause for ground fault. For example, if the voltage potential across the voltage monitoring resistor 166 exceeds a predetermined threshold, the electronic controller 168 may determine that the phase A of the inverter circuit 124 caused the ground fault. In another example, if the voltage potential across the voltage monitoring resistor 166 does not exceed a predetermine threshold, the electronic controller 168 may determine that the phase A of the inverter circuit 124 has not been ground-faulted.

As illustrated in FIG. 3, a negative voltage potential may be detected across the voltage monitoring resistor 166 when phase A caused the ground fault during the first time period (t₁). The negative voltage potential may be detected across the voltage monitoring resistor 166 because the terminal of the voltage monitoring resistor 166 that is coupled to the first resistor 162 and the second resistor 164 may be biased as the negative terminal while the terminal of the voltage monitoring resistor 166 that is coupled to the electrical ground 170 may be biased as the positive terminal. During this time period, when phase A of the inverter circuit 124 caused the ground fault, a current may flow from the positive terminal (e.g., electrical ground 170) of the voltage monitoring resistor 166 to the negative terminal (e.g., mid-point of the first resistor 162 and the second resistor 164) of the voltage monitoring resistor 166 and cause a negative voltage potential across the voltage monitoring resistor 166.

In another exemplary embodiment, a positive voltage potential (not shown) may be detected across the voltage monitoring resistor 166 when phase A causes the ground faulted during a time period, when only phase A is coupled to the negative line 122, while phase B and phase C are coupled to the positive line 120. The positive voltage potential may be detected across the voltage monitoring resistor 166 because the terminal of the voltage monitoring resistor 166 that is coupled to the first resistor 162 and the second resistor 164 may be biased as the positive terminal while the terminal of the voltage monitoring resistor 166 that is coupled to the electrical ground 170 may be biased as the negative terminal. During this time period, when phase A of the inverter circuit 124 caused the ground fault, a current may flow from the positive terminal (e.g., mid-point of the first resistor 162 and the second resistor 164) of the voltage monitoring resistor 166 to the negative terminal (e.g., electrical ground 170) of the voltage monitoring resistor 166 and cause a positive voltage potential across the voltage monitoring resistor 166.

FIG. 4 shows a switching voltage waveform 400 the inverter circuit 124 during a second time period according to another embodiment of the present disclosure. As shown in FIG. 4, the voltage waveform illustrates an operation of the inverter circuit 124 during a second time period (t₂). During the second time period (t₂), phase B of the inverter circuit 124 may be coupled to the positive line 120 (e.g., positive voltage potential) while phase A and phase C of the inverter circuit 124 may be coupled to the negative line 122 (e.g., negative voltage potential). In an exemplary embodiment, the first IGBT switching element 202 may be switched off and the fourth IGBT switching element 208 may be switched on to couple a negative voltage potential (−V_{dc}) on the negative line 122 to the external load 102. As illustrated in the voltage waveform 400, phase A of the inverter circuit 124 may output a negative voltage potential (−V_{dc}) during the second time period (t₂). In another exemplary embodiment, the second IGBT switching element 204 may be switched on and the fifth switching element 210 may be switched off to couple a positive voltage potential on the positive line 120 to the external load 102. As illustrated in the voltage waveform 400, phase B of the inverter circuit 124 may output a positive voltage potential (V_{dc}) during the first time period (t₂). In other exemplary embodiment, the third IGBT switching element 206 may be switched off and the sixth switching element 212 may be switched on to couple a negative voltage potential (−V_{dc}) on the negative line 122 to the external load 102. As illustrated in voltage waveform 400, phase C of the inverter circuit 124 may output a negative voltage potential (−V_{dc}) to the external load 102.

As illustrated in FIG. 4, only phase B of the inverter circuit 124 provides a positive output voltage potential to the external load 102 during the second time period (t₂). The electronic controller 168 may detect a voltage potential (V_{g}) across the voltage monitoring resistor 166 during the second time period (t₂) to determine whether phase B of the inverter circuit 124 is the cause of the ground fault. For example, if the voltage potential across the voltage monitoring resistor 166 exceed a predetermined threshold, the electronic controller 168 may determine that the phase B of the inverter circuit 124 is the cause for ground fault. In another example, if the voltage potential across the voltage monitoring resistor 166 does not exceed a predetermine threshold, the electronic controller 168 may determine that the phase B of the inverter circuit 124 is the cause for ground fault.

As illustrated in FIG. 4, a negative voltage potential may be detected across the voltage monitoring resistor 166 when phase B caused the ground fault during the second time period (t₂), when only phase B is coupled to the positive line 120 while phase A and phase C are coupled to the negative line 122. The negative voltage potential may be detected across the voltage monitoring resistor 166 because the terminal of the voltage monitoring resistor 166 that is coupled to the first resistor 162 and the second resistor 164 may be biased as the negative terminal while the terminal of the voltage monitoring resistor 166 that is coupled to the electrical ground 170 may be biased as the positive terminal. When phase B of the inverter circuit 124 caused ground fault, a current may flow from the positive terminal of the voltage monitoring resistor 166 to the negative terminal of the voltage monitoring resistor 166 and cause a negative voltage potential across the voltage monitoring resistor 166.

In another exemplary embodiment, a positive voltage potential (not shown) may be detected across the voltage monitoring resistor 166 when phase B caused the ground faulted during a time period, when only phase B is coupled to the negative line 122 while phase A and phase C are coupled to the positive line 120. The positive voltage potential may be detected across the voltage monitoring resistor 166 because the terminal of the voltage monitoring resistor 166 that is coupled to the first resistor 162 and the second resistor 164 may be biased as the positive terminal while the terminal of the voltage monitoring resistor 166 that is coupled to the electrical ground 170 may be biased as the negative terminal. For example, when phase B of the inverter circuit 124 caused the ground fault, a current may flow from the positive terminal of the voltage monitoring resistor 166 to the negative terminal of the voltage monitoring resistor 166 and cause a positive voltage potential across the voltage monitoring resistor 166.

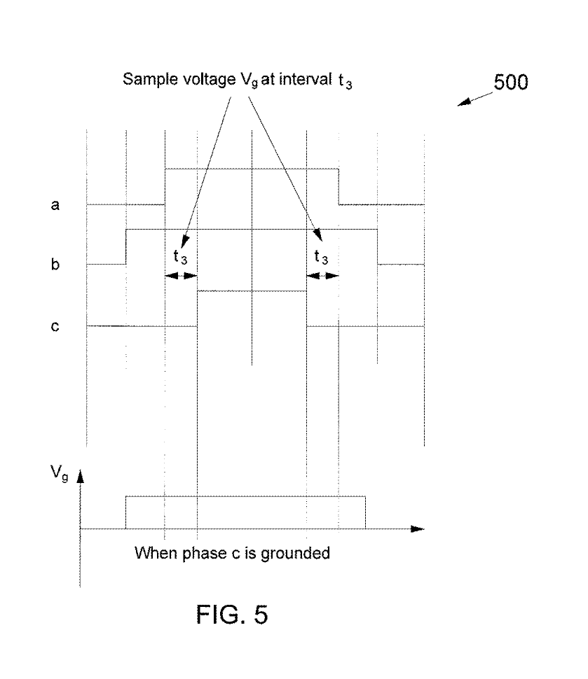

FIG. 5 shows a switching voltage waveform 500 the inverter circuit 124 during a third time period according to another embodiment of the present disclosure. As shown in FIG. 5, the voltage waveform illustrates an operation of the inverter circuit 124 during a third time period (t₃). During the third time period (t₃), phase C of the inverter circuit 124 may be coupled to the negative line 122 while phase A and phase B of the inverter circuit 124 may be coupled to the positive line 120. In an exemplary embodiment, the first IGBT switching element 202 may be switched on and the fourth IGBT switching element 208 may be switched off to couple a positive voltage potential on the positive line 120 to the external load 102. As illustrated in the voltage waveform 500, phase A of the inverter circuit 124 may output a positive voltage potential (V_{dc}) during the third time period (t₃). In another exemplary embodiment, the second IGBT switching element 204 may be switched on and the fifth switching element 210 may be switched off to couple a positive voltage potential on the positive line 120 to the external load 102. As illustrated in the voltage waveform 500, phase B of the inverter circuit 124 may output a positive voltage potential (V_{dc}) during the third time period (t₃). In other exemplary embodiment, the third IGBT switching element 206 may be switched off and the sixth switching element 212 may be switched on to couple a negative voltage potential (−V_{dc}) on the negative line 122 to the external load 102. As illustrated in voltage waveform 500, phase C of the inverter circuit 124 may output a negative voltage potential (−V_{dc}) to the external load 102.

As illustrated in FIG. 5, only phase C of the inverter circuit 124 provides a negative voltage potential to the external load 102 during the third time period (t₃). The electronic controller 168 may detect a voltage potential (V₉) across the voltage monitoring resistor 166 during the third time period (t₃) to determine whether phase C of the inverter circuit 124 is the cause of the ground fault. For example, if the voltage potential across the voltage monitoring resistor 166 exceed a predetermined threshold, the electronic controller 168 may determine that the phase C of the inverter circuit 124 is the cause of ground fault. In another example, if the voltage potential across the voltage monitoring resistor 166 does not exceed a predetermine threshold, the electronic controller 168 may determine that the phase C of the inverter circuit 124 has not been ground-faulted.

As illustrated in FIG. 5, a positive voltage potential may be detected across the voltage monitoring resistor 166 when phase C caused the ground fault during the third time period (t₃). The positive voltage potential may be detected across the voltage monitoring resistor 166 because the terminal of the voltage monitoring resistor 166 that is coupled to the first resistor 162 and the second resistor 164 may be biased as the positive terminal while the terminal of the voltage monitoring resistor 166 that is coupled to the electrical ground 170 may be biased as the negative terminal. When phase C of the inverter circuit 124 is the cause of the ground fault, a current caused by the negative voltage potential (−V_{dc}) from the negative line 122 of phase C of the inverter circuit 124 may flow from the positive terminal of the voltage monitoring resistor 166 to the negative terminal of the voltage monitoring resistor 166 and cause a positive voltage potential across the voltage monitoring resistor 166.

In another exemplary embodiment, a negative voltage potential (not shown) may be detected across the voltage monitoring resistor 166 when phase C caused the ground fault during a time period, when only phase C is coupled to the positive line 120 while phase A and phase B are coupled to the negative line 122. The negative voltage potential may be detected across the voltage monitoring resistor 166 because the terminal of the voltage monitoring resistor 166 that is coupled to the first resistor 162 and the second resistor 164 may be biased as the negative terminal while the terminal of the voltage monitoring resistor 166 that is coupled to the electrical ground 170 may be biased as the positive terminal. When phase C of the inverter circuit 124 caused the ground fault, a current caused by the positive voltage potential (+V_{dc}) from the negative line 122 of phase C of the inverter circuit 124 may flow from the positive terminal of the voltage monitoring resistor 166 to the negative terminal of the voltage monitoring resistor 166 and cause a negative voltage potential across the voltage monitoring resistor 166.

### INDUSTRIAL APPLICABILITY

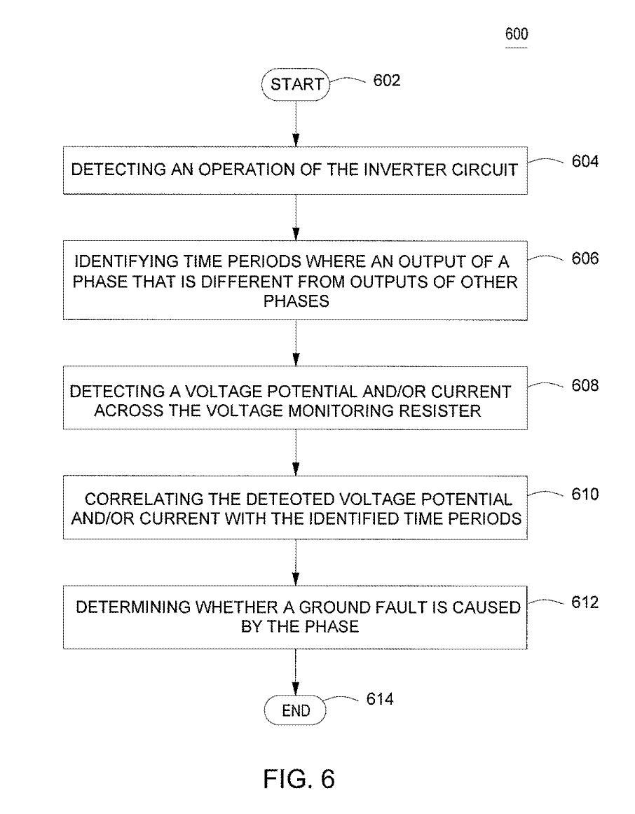

FIG. 6 is a flowchart illustrating a method 600 for detecting a ground fault according to an embodiment of the present disclosure. This exemplary method 600 may be provided by way of example, as there are a variety of ways to carry out the method. The method 600 shown in FIG. 6 can be executed or otherwise performed by one or a combination of various systems. The method 600 is described below may be carried out by the elements and circuitry shown in FIGS. 1 and 2, by way of example, and various elements and circuitry of the power supply system 100 are referenced in explaining the example method of FIG. 6. Each block shown in FIG. 6 represents one or more processes, methods or subroutines carried out in exemplary method 600. Referring to FIG. 6, exemplary method 600 may begin at block 602.

At block 604, detecting an operation of the inverter circuit 124. For example, an electronic controller 168 may detect an output of various phases of the inverter circuit 124. For example, the electronic controller 168 may detect an operation (e.g., switching on and off) of the plurality of IGBT switching elements 202-212 to determine an output voltage potential of various phases of the inverter circuit 124. In an exemplary embodiment, the electronic controller 168 may detect that the first IGBT switching element 202 may be switched on and the fourth switching element 208 may be switched off. The electronic controller 168 may determine that the phase A of the inverter circuit 124 may output a positive voltage potential (V_{dc}) from the positive line 120. In another exemplary embodiment, the electronic controller 168 may detect that the second IGBT switching element 204 may be turned on and the fifth switching element 210 may be turned off. The electronic controller 168 may determine that phase B of the inverter circuit 124 may output a positive voltage potential (V_{dc}) from the positive line 120. In other exemplary embodiments, the electronic controller 168 may detect that the third IGBT switching element 206 may be switched off and the sixth switching element 212 may be switched on. The electronic controller 168 may determine that phase C of the inverter circuit 124 may output a negative voltage potential (−V_{dc}) from the negative line 122.

At block 606, identifying time periods where an output of a phase of the inverter circuit 124 that is different from outputs of other phases of the inverter circuit 124. For example, the electronic controller 168 may identify one or more time periods where phase A of the inverter circuit 124 outputs a positive voltage potential (VA from the positive line 120 while phase B and phase C output a negative voltage potential (−V_{dc}) from the negative line 122. The electronic controller 168 may identify one or more time periods where phase A of the inverter circuit 124 outputs a negative voltage potential (−V_{dc}) from the negative line 122 while phase B and phase C output a positive voltage potential (V_{dc}) from the positive line 120. In another exemplary embodiment, the electronic controller 168 may identify one or more time period where phase B of the inverter circuit 124 outputs a positive voltage potential (V_{dc}) from the positive line 120 while phase A and phase C output a negative voltage potential (−V_{ac}) from the negative line 122. The electronic controller 168 may identify one or more time periods where phase B of the inverter circuit 124 outputs a negative voltage potential (−V_{dc}) from the negative line 122 while phase A and phase C output a positive voltage potential (V_{dc}) from the positive line 120. In other exemplary embodiments, the electronic controller 168 may identify one or more time periods where phase C of the inverter circuit 124 outputs a positive voltage potential (V_{dc}) from the positive line 120 while phase A and phase B output a negative voltage potential (−V_{dc}) from the negative line 122. The electronic controller 168 may identify one or more time periods where phase C of the inverter circuit 124 outputs a negative voltage potential (−V_{dc}) from the negative line 122 while phase A and phase B output a positive voltage potential (VA from the positive line 120.

At block 608, detecting a voltage potential and/or a current across the voltage monitoring resistor 166. For example, the electronic controller 168 may continuously detect a voltage potential across the voltage monitoring resistor 166. In another example, the electronic controller 168 may periodically detect a voltage potential across the voltage monitoring resistor 166. In an exemplary embodiment, the electronic controller 168 may detect a voltage potential across the voltage monitoring resistor 166 during the time periods where an output of a phase of the inverter circuit 124 is different from outputs of other phases of the inverter circuit 124.

At block 610, correlating the detected voltage potential across with voltage monitoring resistor 166 with the identified time periods where an output of a phase of the inverter circuit 124 is different from outputs of other phases of the inverter circuit 124. For example, the electronic controller 168 may identify the voltage potentials detected across the voltage monitoring resistor 166 during the time periods where an output of a phase of the inverter circuit 124 is different from outputs of other phases of the inverter circuit 124.

At block 612, determining whether a ground fault is caused by a phase of the inverter circuit 124. For example, the electronic controller 168 may determine whether the voltage potential and/or current detected during the identified time period, where an output of a phase of the inverter circuit 124 is different from outputs of other phases of the inverter circuit 124, exceeds a predetermined threshold. If the voltage potential exceed the predetermined threshold, the electronic controller 168 may determine that the phase of the inverter circuit 124 that is different from other phases of the inverter circuit 124 caused ground fault. If the voltage potential does not exceed the predetermined threshold, the electronic controller 168 may determine that the phase of the inverter circuit 124 that is different from other phases of the inverter circuit 124 is not the cause for ground fault.

At block 614, the method for determining a ground fault of a power supply system 100 may end and provide operator with diagnostic result of ground-fault localization.

The disclosed power supply system 100 having ground fault detection may provide accurate detection of ground fault of an inverter circuit 124 of the power supply system 100. The disclosed system may be used to detect a ground fault during each phase of an inverter circuit 124 in order to determine which phase of the inverter circuit 124 caused the ground fault.

The disclosure may be implemented in any type of computing devices, such as, e.g., a desktop computer, personal computer, a laptop/mobile computer, a personal data assistant (PDA), a mobile phone, a tablet computer, cloud computing device, and the like, with wired/wireless communications capabilities via the communication channels, devices with such functions may be utilized in various high voltage applications, including, but not limited to, following applications, such as construction machines, mining machines, industrial drives, public transportations and stand-by electrical power generation, etc.

Further in accordance with various embodiments of the disclosure, the methods described herein are intended for operation with dedicated hardware implementations including, but not limited to, PCs, PDAs, semiconductors, application specific integrated circuits (ASIC), programmable logic arrays, cloud computing devices, and other hardware devices constructed to implement the methods described herein.

It should also be noted that the software implementations of the disclosure as described herein are optionally stored on a tangible storage medium, such as: a magnetic medium such as a disk or tape; a magneto-optical or optical medium such as a disk; or a solid state medium such as a memory card or other package that houses one or more read-only (non-volatile) memories, random access memories, or other re-writable (volatile) memories. A digital file attachment to email or other self-contained information archive or set of archives is considered a distribution medium equivalent to a tangible storage medium. Accordingly, the disclosure is considered to include a tangible storage medium or distribution medium, as listed herein and including art-recognized equivalents and successor media, in which the software implementations herein are stored.

The many features and advantages of the disclosure are apparent from the detailed specification, and, thus, it is intended by the appended claims to cover all such features and advantages of the disclosure which fall within the true spirit and scope of the disclosure. Further, since numerous modifications and variations will readily occur to those skilled in the art, it is not desired to limit the disclosure to the exact construction and operation illustrated and described, and, accordingly, all suitable modifications and equivalents may be resorted to that fall within the scope of the disclosure.

What is claimed is:

1. A ground fault detection system, comprising:
a direct current (DC) voltage source;
an alternating current (AC) device;
an inverter, coupled to the DC voltage source, the AC device and an electrical ground, including:
a positive rail,
a negative rail, and
a plurality of switch elements, wherein each of the plurality of switch elements is coupled to the positive rail, the negative rail and the AC device;
a voltage monitoring device coupled to the positive rail, the negative rail and the electrical ground; and
an electronic controller, coupled to the inverter and the voltage monitoring device, configured to:
control the plurality of switching elements,
sample a voltage potential across the voltage monitoring device at predetermined time periods, and
determine a ground fault of the inverter based at least in part on the sampled voltage potential and the predetermined time periods.

2. The ground fault detection system of claim 1, wherein the DC voltage source comprises a power generator.

3. The ground fault detection system of claim 1, wherein the power generator is an AC power generator.

4. The ground fault detection system of claim 3, wherein the DC voltage source comprises a rectifier circuit that converts AC power to DC power.

5. The ground fault detection system of claim 4, wherein the rectifier circuit is a three-phase rectifier circuit.

6. The ground fault detection system of claim 5, wherein the three-phase rectifier comprises three-sets of full-wave rectifier circuits.

7. The ground fault detection system of claim 1, wherein the plurality of switching elements are insulated-gate bipolar transistor (IGBT) inverter circuits that comprise an insulated-gate bipolar transistor and a diode.

8. The ground fault detection system of claim 1, wherein the voltage monitoring device comprises a first resistor coupled to the positive rail and a second resistor coupled to the negative rail.

9. The ground fault detection system of claim 8, wherein the voltage monitoring device comprises a voltage monitoring resistor coupled to the first resistor, the second resistor and an electrical ground.

10. The ground fault detection system of claim 9, wherein the electronic controller samples the voltage potential across the voltage monitoring resistor.

11. The ground fault detection system of claim 1, wherein the electronic controller is further configured to correlate the sampled voltage potential with the predetermined time periods in order to determine a cause of the ground fault of the inverter circuit.

12. The ground fault detection system of claim 1, wherein the predetermined time periods comprises a time period where a phase of operation of the inverter circuit is different from other phases of operation of the inverter circuit.

13. A method for detecting a ground fault in a power supply system, comprising:
detecting outputs of a plurality of phases of an inverter circuit including a positive rail, a negative rail, and a plurality of switch elements;
identifying one or more time periods when an output of one phase of the plurality of phases is different from the outputs of the remaining phases of the plurality of phases of the inverter circuit;
detecting a voltage potential across a voltage monitoring device that is coupled to the positive rail and the negative rail; and
determining a ground fault of the power supply system based at least in part on the voltage potential across the voltage monitoring device during the one or more periods.

14. The method of claim 13, further comprising correlating the detected voltage potential across the voltage monitoring device to the one or more time periods.

15. The method of claim 13, wherein detecting outputs of a plurality of phases of an inverter circuit comprises detecting a state of the plurality of switching elements.

16. The method of claim 13, wherein detecting a voltage potential across a voltage monitoring device comprises continuously detecting the voltage potential across the voltage monitoring device.

17. The method of claim 13, wherein detecting a voltage potential across a voltage monitoring device comprises periodically detecting the voltage potential across the voltage monitoring device.

18. The method of claim 17, wherein periodically detecting the voltage potential across the voltage monitoring device comprises detecting the voltage potential across the voltage monitoring device during the one or more time periods.

19. The method of claim 13, wherein determining a ground fault comprises determining whether the voltage potential across the voltage monitoring device exceeds a threshold during the one or more time periods.

20. The method of claim 19, wherein determining a ground fault comprises determining that the phase having the output that is different from the output of the remaining phases of the plurality of phases caused the ground fault when the voltage potential across the voltage monitoring device exceeds the threshold.
